(19) United States
(12) Patent Application Publication
(10) Pub. No.: US 2010/0109118 A1
(43) Pub. Date: May 6, 2010

(54) SEMICONDUCTOR DEVICE

(75) Inventors: MASATO SAKURAI, Kanagawa (JP); AKIHIRO SAWAIRI, Kanagawa (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/603,592

(22) Filed: Oct. 22, 2009

(30) Foreign Application Priority Data
Oct. 31, 2008 (JP) 2008-281580

(51) Int. Cl. H01L 27/06

(52) U.S. Cl. 257/501; 257/E27.018

(57) ABSTRACT

A semiconductor device of the present invention includes a semiconductor layer, a low withstand voltage transistor, and a high withstand voltage transistor. In the low withstand voltage transistor, a first high concentration collector region and a first base region contact with a first low concentration collector region provided in the semiconductor layer. In the high withstand voltage transistor, a second high concentration collector region and a second base region contact a second low concentration collector region provided in the semiconductor layer. Further, the second high concentration collector region and the second base region are configured such that the distance between the second high concentration collector region and the second base region in a parallel direction to a main surface of the semiconductor layer is longer than the distance between the first high concentration collector region and the first base region.

### BACKGROUND

1. Field of the Invention

The present invention relates to a semiconductor device.

2. Description of Related Art

Semiconductor device designs for a semiconductor device with different circuits mounted thereon to have multiple functions are increasing along with higher integration and more sophisticated functions in recent years. A circuit is composed of a transistor. Transistors are disclosed in Japanese Unexamined Patent Application Publication Nos. 7-231043, 7-326630, and 2000-294563, for example. Required withstand voltage for a transistor differs depending on the circuit, however in general, there is a trade-off relation between the withstand voltage and an operating speed of a transistor. Therefore, when a transistor is designed in accordance with a circuit requesting for the highest withstand voltage, the performance of the circuit not requiring for high withstand voltage cannot be maximized. It is desirable to be able to produce transistors with different withstand voltages in one semiconductor device so that the circuit performance can be maximized. Further, it is desirable that these transistors can be produced at a low cost.

One method for answering this request is disclosed in Japanese Unexamined Patent Application Publication No. 7-231043. The structure of a related art is described with reference to FIG. 7. FIG. 7 is a cross-sectional diagram illustrating the structure of a semiconductor device according to a related art. FIG. 7 is equivalent to FIG. 1 of Japanese Unexamined Patent Application Publication No. 7-231043.

A semiconductor device disclosed in Japanese Unexamined Patent Application Publication No. 7-231043 includes a vertical npn bipolar transistor 1 which emphasizes the operating speed and a vertical npn bipolar transistor 2 which emphasizes high withstand voltage. The vertical npn bipolar transistor 2 includes a collector buried region 2a, a base region 2c formed above an n well 2b over the collector buried region 2a, and an emitter region 2d formed above and middle of the base region 2c.

As with the vertical npn bipolar transistor 2, the vertical npn bipolar transistor 1 also includes a collector buried region 1a, an n well 1b, a base region 1c, and an emitter region 1d. The vertical npn bipolar transistor 1 further includes an n type impurity region 1e. The N type impurity region 1e is formed by introducing an n type impurity only into the n well 1b (collector region) between the base region 1c and the collector buried region 1a in directly under the emitter region 1d when forming them over a semiconductor substrate 3. Then a SIC (Selectively Ion-implanted Collector) structure is formed in the vertical bipolar transistor 1 which emphasizes the operating speed. In this way, it is possible to mount transistors with two different withstand voltages by determining whether or not the SIC structure is formed for each transistor.

Japanese Unexamined Patent Application Publication No. 7-326630 discloses a method of forming a bipolar transistor over a SOI (Silicon on Insulator) substrate. The structure of a semiconductor device is explained along with the manufacturing method with reference to FIG. 8. FIG. 8 is a cross-sectional diagram illustrating another structure of a semiconductor device according to a related art. FIG. 8 is equivalent to FIG. 5 of Japanese Unexamined Patent Application Publication No. 7-326630.

Firstly, a collector region 11 and a base region 12 are formed in a body silicon layer over an insulating layer 10 of a SOI substrate by implanting a dopant. Then, a polysilicon layer 13 is formed over the base region 12. Next, ions are selectively implanted to form an emitter terminal region and a collector terminal region 14 which are highly doped to have n⁺ conductive type. Then, by a heat treatment process, the highly doped dopant diffuses from the polysilicon layer 13 as the emitter terminal region to form an emitter region 16. After that, ions are selectively implanted to form a base terminal region 15 which is highly doped to have a p⁺ conductive type. The doping concentration of the collector region 11 as a region minimally doped is selected to be low to the degree that the collector region 11 is completely depleted.

### SUMMARY

The present inventors have found a problem that in the technique disclosed in Japanese Unexamined Patent Application Publication No. 7-231043, SIC structures are selectively formed for each transistor, thereby increasing the processes. In order to mount transistors having 3 or more types of withstand voltages, the manufacturing processes increase in proportion to the number of types to mount.

Furthermore, in order to increase the withstand voltage of the vertical npn bipolar transistor 2 for high withstand voltage, the distance between the collector buried region 2a and the base region 2c must be increased. Consequently, the method to increase the thickness of an epitaxial layer 4Epi is well known. However, when the thickness of the epitaxial layer 4Epi is increased, adverse effects are generated to the vertical npn bipolar transistor 1 in which the SIC structure is formed, such as an increase in a collector resistance. It further makes it difficult to form the collector extraction region 2f deeply at one time. This requires to grow epitaxial or a method to form the collector extraction region 2f in two processes, which leads to increase the cost.

The technique disclosed in Japanese Unexamined Patent Application Publication No. 7-326630 adopts the SOI structure, in which the withstand voltage between collector and base is determined in the horizontal direction. This structure is similar to the present invention. However, in the manufacturing method and the structure disclosed in Japanese Unexamined Patent Application Publication No. 7-326630, the impurity concentration of the collector terminal region 14 must be selectively variable to control the withstand voltage, so there is not much difference from selectively forming the SIC structure as in the technique disclosed in Japanese Unexamined Patent Application Publication No. 7-231043.

To solve the above problem, a semiconductor device according to the present invention includes a semiconductor layer, a low withstand voltage transistor in which a first high concentration collector region and a first base region contact with a first low concentration collector region provided to the semiconductor layer, and high withstand voltage transistor in which a second high concentration collector region and a second base region contact a second low concentration collector region provided to the semiconductor layer, where the second high concentration collector region and the second base region are configured such that the distance between the second high concentration collector region and the second base region in a parallel direction to a main surface of the semiconductor layer is longer than the distance between the first high concentration collector region and the first base region. This enables to easily form transistors with different withstand voltages.

The present invention provides a semiconductor device that facilitates to form transistors with different withstand voltages.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross-sectional diagram illustrating the structure of a semiconductor device according to a first exemplary embodiment;

FIG. 2 is a graph illustrating the relationship between the concentration of the low concentration collector region, the distance between the high concentration collector region and the base region, and the withstand voltage between collector and base;

FIG. 3 is a cross-sectional diagram illustrating the structure of a semiconductor device according to a second exemplary embodiment;

FIG. 4 is a cross-sectional diagram illustrating the structure of a semiconductor device according to a third exemplary embodiment;

FIG. 5 is a cross-sectional diagram illustrating the structure of a semiconductor device according to a fourth exemplary embodiment;

FIG. 6 is a cross-sectional diagram illustrating the structure of a semiconductor device according to a fifth exemplary embodiment;

FIG. 7 is a cross-sectional diagram illustrating the structure of a semiconductor device according to a related art; and

FIG. 8 is a cross-sectional diagram illustrating another structure of a semiconductor device according to a related art.

### DETAILED DESCRIPTION OF THE EXEMPLARY EMBODIMENTS

### First Exemplary Embodiment

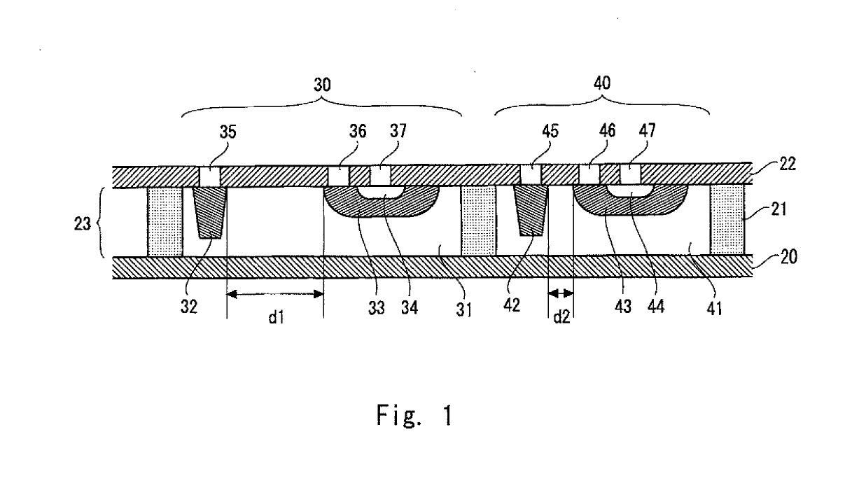

The structure of a semiconductor device is explained with reference to FIG. 1. FIG. 1 is a cross-sectional diagram illustrating the structure of the semiconductor device. The semiconductor device has multiple transistors. An npn bipolar transistor is explained as an example of the transistor. Note that in this exemplary embodiment, a transistor is a horizontal transistor in which a current flows in the horizontal direction.

A semiconductor device is formed using a SOI (Silicon on Insulator) substrate. The SOI substrate is composed of an insulating layer 20 and a body silicon layer 23 formed thereover as a semiconductor layer. The semiconductor device has 2 or more transistors with different withstand voltages. In this example, the two transistors included in the semiconductor device are a transistor 30 which emphasizes high withstand voltage and a transistor 40 which emphasizes operating speed with low withstand voltage.

In the transistor 30, a low concentration collector region 31, a high concentration collector region 32, a base region 33, and an emitter region 34 are formed in the body silicon layer 23. The low concentration collector region 31 is an n type semiconductor layer including an n type impurity, such as phosphorus, in a low concentration. In the low concentration collector region 31, the impurity is included in the low concentration of about 1×10¹⁴ to 1×10¹⁶ cm⁻³, for example. The high concentration collector region 32 is an n type semiconductor layer including an n type impurity, such as phosphorus, in a high concentration. In the high concentration collector region 32, the impurity is included in the high concentration of about 1×10¹⁸ to 1×10²¹cm⁻³, for example. The base region 33 is a p type semiconductor layer including a p type impurity, such as boron. The emitter region 34 is an n type semiconductor layer including an n type impurity, such as phosphorus, in a high concentration. Upper edges of the low concentration collector region 31, the high concentration collector region 32, the base region 33, and the emitter region 34 are in contact with the main surface of the body silicon layer 23 (the surface opposite to the insulating layer 20).

The emitter region 34 is formed near the main surface of the body silicon layer 23. The base region 33 is formed in the upper part of the body silicon layer 23. The base region 33 is formed to surround the emitter region 34 except its upper edge. Accordingly, the base region 33 is formed between the low concentration collector region 31 and the emitter region 34. The high concentration collector region 32 is spaced apart from the base region 33. The high concentration collector region 32 is formed from the lower edge or the central part to the upper edge in the height direction of the body silicon layer 23. The height of the high concentration collector region 32 is higher than the height of the base region 33. The low concentration collector region 31 is formed in the other part of the body silicon layer 23. Accordingly, the low concentration collector region 31 is formed between the high concentration collector region 32 and the base region 33. The high concentration collector region 32 and the base region 33 are in contact with the low concentration collector region 31. The high concentration collector region 32, the low concentration collector region 31, the base region 33, and the emitter region 34 are provided in order on the main surface of the body silicon layer 23.

The collector electrode 35, the base electrode 36, and the emitter electrode 37 are formed over the body silicon layer 23. The collector electrode 35, the base electrode 36, and the emitter electrode 37 are provided in order on the main surface of the body silicon layer 23. Specifically, the collector electrode 35 is formed in contact with the high concentration collector region 32. The base electrode 36 is formed in contact with the base region 33 between the high concentration collector region 32 and the emitter region 34. The emitter electrode 37 is formed in contact with the emitter region 34.

As with the above transistor 30, the transistor 40 includes a low concentration collector region 41, a high concentration collector region 42, a base region 43, an emitter region 44, a collector electrode 45, the base electrode 46, and an emitter electrode 47. In the transistors 30 and 40, the distances between the high concentration collector regions 32 and 42, and the base regions 33 and 43 are different. More specifically, a distance d1 between the high concentration collector region 32 and the base region 33 is different from a distance d2 between the high concentration collector region 42 and the base region 43. The distances d1 and d2 are distances (gap) between the above components in the parallel direction to the main surface of the body silicon layer 23. In other words, in the transistors 30 and 40, the widths of the low concentration collector regions 31 and 41 existing between the high concentration collector regions 32 and 42 and the base regions 33 and 43 are different. Further, in the transistors 30 and 40, the distances between the collector electrodes 35 and 45 and the base electrodes 36 and 46 are different.

More specifically, the distances and widths of the above components in the transistor 30 are larger than those of the transistor 40. Accordingly, in the transistor 30 which emphasizes high withstand voltage, the high concentration collector region 32 and the base region 33 are spaced apart. To be more specific, the distance d1 is longer than the distance d2. Therefore, the entire planar size of the transistor 30 is larger than that of the transistor 40. Other structure of the transistor 40 is substantially the same as the transistor 30. Accordingly, the positional relationship between components of the transistors 30 in the height direction (vertical direction to the main surface of the body silicon layer 23) is the same as that between the corresponding components of the transistors 40. Further, the positional relationship between components of the transistors 30 in the horizontal direction (parallel direction to the main surface of the body silicon layer 23) is different from that between the corresponding components of the transistors 40. Moreover, corresponding regions in the transistors 30 and 40 have substantially the same impurity concentration.

An insulating layer 21 for separating elements is formed in the body silicon layer 23 between adjacent transistors. An insulating layer 22 is formed over the body silicon layer 23 except the region where the collector electrodes 35 and 45, the base electrodes 36 and 46, and the emitter electrodes 37 and 47 are formed thereover. The semiconductor device according to the exemplary embodiment is formed in this way.

In the transistors 30 and 40, a current flows between the high concentration collector regions 32 and 42 and the emitter regions 34 and 44. In this exemplary embodiment, the distance between the high concentration collector region 32 and the base region 33 of the transistor 30 is longer than that of the transistor 40, as mentioned above. Accordingly, as compared with the transistor 40, the transistor 30 has a wider width of the low concentration collector region 31 between the high concentration collector region 32 and the base region 33. In other words, the transistor 30 has a longer current path in the low concentration collector region 31 than the transistor 40. Further, the low concentration collector regions 31 and 41 are formed in a low concentration to the degree that the low concentration collector regions 31 and 41 are depleted. Therefore, the transistor 30 has a higher withstand voltage than the transistor 40. Further, the transistor 40 has faster operating speed than the transistor 30. As described so far, the withstand voltage of the transistors, specifically the withstand voltage between collector and base, varies according to the distance between the high concentration collector region 32 and 42 and the base region 33 and 43.

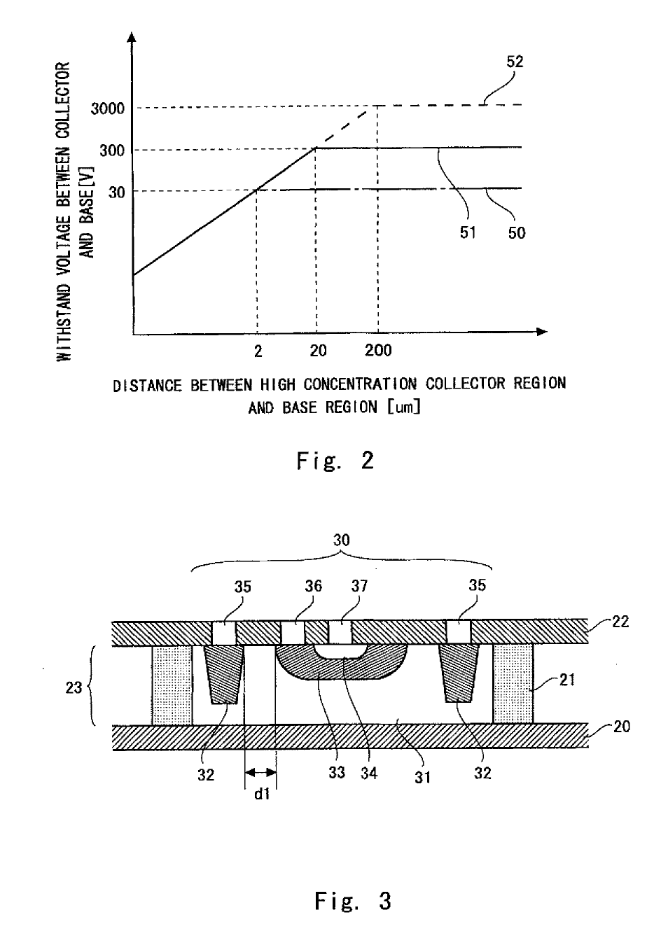

The withstand voltage between collector and base varies also according to the impurity concentration of the low concentration collector regions 31 and 41. FIG. 2 illustrates the relationship between the distance between the high concentration collector regions 32 and 42 and the base regions 33 and 43, and the withstand voltage between collector and base according to the impurity concentration of the low concentration collector regions 31 and 41. FIG. 2 indicates the calculation result in case of an abrupt junction in which one side has infinite concentration. In FIG. 2, the horizontal axis represents the distance [um] between the high concentration collector regions 32 and 42 and the base regions 33 and 43. The vertical axis represents the withstand voltage [V] between collector and base.

As illustrated in FIG. 2, up to a certain distance, the withstand voltage between collector and base is almost proportional to the distance between the high concentration collector regions 32 and 42 and the base regions 33 and 43. Then, after exceeding the certain distance, the withstand voltage between collector and base does not increase and stays at a constant value. The certain distance is the maximum distance having the substantially proportional relationship with the withstand voltage between collector and base. The maximum distance is the distance to which the field strength reaches the limit (For Si, about 30[V/um]) to cause an avalanche breakdown phenomenon.

The maximum distance is determined by the impurity concentration of the low concentration collector regions 31 and 41. Further, even if the impurity concentration of the low concentration collector regions 31 and 41 changes, the value of the withstand voltage between collector and base when the distances between the high concentration collector regions 32 and 42 and base regions 33 and 43 are 0, and the gradient to the maximum distance of the straight line of FIG. 2 are substantially the same. The lower the impurity concentration of the low concentration collector regions 31 and 41, the longer the maximum distance and higher the upper limit of the withstand voltage of the collector and base become. Accordingly, the lower the impurity concentration of the low concentration collector regions 31 and 41, the larger the difference of the withstand voltage of the transistors caused by a change in the distance between the high concentration collector regions 32 and 42 and the base regions 33 and 43.

Specifically, as denoted by the sign 50, with the impurity concentration of the low concentration collector regions 31 and 41 up to 1×10¹⁶ [atom/cm³], the maximum distance (marginal distance) is about 2 [um] and the junction withstand voltage is about 30[V]. As denoted by the sign 51, with the impurity concentration of the low concentration collector regions 31 and 41 up to 1×10¹⁵ [atom/cm³], the maximum distance (marginal distance) is about 20 [um] and the junction withstand voltage is about 300[V]. As denoted by the sign 52, with the impurity concentration of the low concentration collector regions 31 and 41 up to 1×10¹⁴ [atom/cm³], the maximum distance (marginal distance) is about 200 [um] and the junction withstand voltage is about 3000[V]. As described above, the withstand voltage properties of the transistors 30 and 40 are determined by the distances between the high concentration collector regions 32 and 42 and the base regions 33 and 43, and the impurity concentrations of the low concentration collector regions 31 and 41.

Thus the semiconductor device is designed in consideration of the following two points.

(1) The impurity concentration of the low concentration collector region is designed to be low so as to ensure sufficient withstand voltage of the transistor, which is required to have the highest withstand voltage among the multiple transistors.
(2) The position of the high concentration collector region is designed in a range to satisfy a desired withstand voltage for each transistor.

Furthermore, in the structure of this exemplary embodiment, the bottom surface of the transistor is formed by the insulating layer 20 as a Box (Buried Oxide) layer of a SOI substrate in contrast to Japanese Unexamined Patent Application Publication No. 7-231043 in which the bottom surface of the transistor is formed by the high concentration collector region. More specifically, in this exemplary embodiment, in each of the transistors 30 and 40, the high concentration collector regions 32 and 42, the low concentration collector regions 31 and 41, the base regions 33 and 43, and the emitter regions 34 and 44 are formed in order in the horizontal direction. Therefore, a current flows in the horizontal direction in contrast to Japanese Unexamined Patent Application Publication No. 7-231043 in which a current flows in the vertical direction. Thus the withstand voltage is not determined by the design of the vertical direction (distance and concentration) but the withstand voltage can be determined by the design of horizontal direction.

Accordingly, it is simple to change the withstand voltages of the transistors 30 and 40, only requiring to change the distance in the vertical direction of the high concentration collector regions 32 and 42 and the base regions 33 and 43. For example, it is simple and only requires to adjust the positions of the high concentration collector regions 32 and 42 in the vertical direction. Further, sufficient withstand voltage can be achieved even without forming a thick body silicon layer 23, thus it is hard to cause an adverse effect to the transistor 40 which emphasizes the operating speed, such as an increase in the collector resistance. It is also simple to form the insulating layer 21.

More specifically, the closer the positions of the high concentration collector regions 32 and 42 to the base regions 33 and 43, the faster the operating speed of the transistors to be formed. On the contrary, the farther the positions of the high concentration collector regions 32 and 42 to the base regions 33 and 43, the higher the withstand voltage of the transistors to be formed. In this way, it is possible to form transistors with different withstand voltages over one substrate by adjusting the distances between the high collector regions and the base regions for each transistor.

The high concentration collector regions 32 and 42 are formed by injecting an impurity through masks having openings in the position corresponding to the high concentration collector regions 32 and 42. Adjusting the shapes of the masks facilitates to form transistors with different withstand voltages without increasing the manufacturing processes. This leads to improve the productivity. Accordingly, it only requires a mask designing to control the withstand voltage regardless of the manufacturing process, thus it is easy to mount transistors with several withstand voltages.

### Second Exemplary Embodiment

In this exemplary embodiment, the high concentration collector region 32 is formed to the both sides of the base region 33. The structure of the semiconductor device according to this exemplary embodiment is explained with reference to FIG. 3. FIG. 3 is a cross-sectional diagram illustrating the structure of the semiconductor device. It is noted that only one transistor is illustrated in FIG. 3, however multiple transistors with different withstand voltages are formed as with the first exemplary embodiment. Further, the transistor 30 is explained as an example, however it is applicable also to the transistor 40. The explanation common to the first exemplary embodiment is omitted or simplified as appropriate.

As illustrated in FIG. 3, the high concentration collector regions 32 are formed to the both sides of the base region 33, respectively. That is, the base region 33 is formed between two high concentration collector regions 32. Further, these two high concentration collector regions 32 have substantially the same shape and size. Two collector electrodes 35 are formed in contact with the two high concentration collector regions 32. That is, the collector electrode 35, the base electrode 36, the emitter electrode 37, and the collector electrode 35 are formed in order over the body silicon layer 23. This structure enables to reduce the collector resistance and improve the operating speed. The withstand voltage in this case is determined by the distance between the high concentration collector region 32, which is closer to the base region 33 among the two high concentration collector regions 32, and the base region 33. That is, the withstand voltage is determined by the shortest distance (distance in the horizontal direction, to be specific) between the high concentration collector region 32 and the base region 33.

Then, in the several transistors, transistors with different withstand voltages can be easily formed over the same SOI substrate by changing the distance between the base region 33 and the high concentration collector region 32. Further, as with the first exemplary embodiment, it only requires to adjust the shape of the mask in order to produce a semiconductor device. Thus it is simple and also enables to improve the productivity. Although two high concentration collector regions 32 are formed in this example, 3 or more may be formed. Moreover, several high concentration collector regions may be formed only in the transistor which emphasizes the operating speed or several high concentration collector regions may be formed in all the transistors.

### Third Exemplary Embodiment

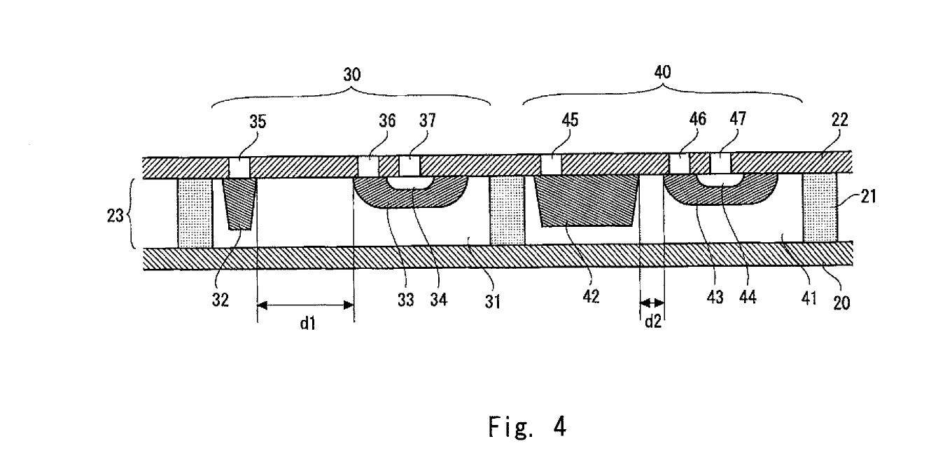

In this exemplary embodiment, the sizes of the high concentration collector regions 32 and 42 are changed. The structure of a semiconductor device according to this exemplary embodiment is explained with reference to FIG. 4. FIG. 4 is a cross-sectional diagram illustrating the structure of the semiconductor device. The explanation common to the first exemplary embodiment is omitted or simplified as appropriate.

As illustrated in FIG. 4, only in the transistor 40 which has low withstand voltage and emphasizes the operating speed, the size of the high concentration collector region 42 is increased. More specifically, the width of the high concentration collector region 42 in the transistor 40 is wider than that of the transistor 30. Moreover, the heights of the high concentration collector regions 32 and 42 are substantially the same. The entire planar sizes of the transistor 30 and 40 are substantially the same.

Further, in the transistors 30 and 40, the distances between the collector electrodes 35 and 45 and the base electrodes 36 and 46 are substantially the same. The distances between the base electrodes 36 and 46 and the emitter electrodes 37 and 47 are also substantially the same. That is, in the transistors 30 and 40, only the widths of the high concentration collector regions 32 and 42 are different and size and the positional relationship or the like of the other corresponding components are substantially the same. This makes the transistor design easier. To change the withstand voltage design of the product which has already been designed, it only requires to modify the mask to determine the high concentration collector regions 32 and 42. This simplifies the design change.

As described so far, the distances between the high concentration collector regions 32 and 42 and the base regions 33 and 43 change by changing the sizes, specifically the width, of the high concentration collector regions 32 and 42. To be specific, the distance d1 between the high concentration collector region 32 and the base region 33 is made larger than the distance d2 between the high concentration collector region 42 and the base region 43. This enables to control the withstand voltage only by the sizes of the high concentration collector regions 32 and 42, and the transistors 30 and 40 with different withstand voltages can be easily formed.

### Fourth Exemplary Embodiment

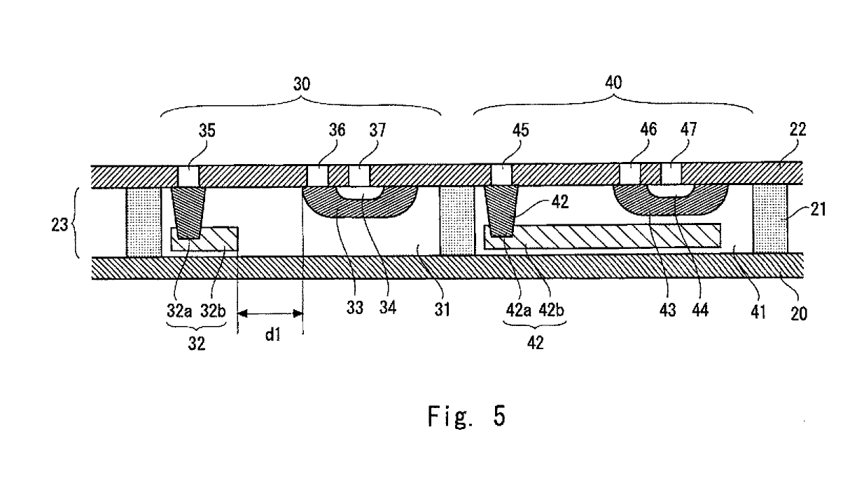

In this exemplary embodiment, a buried high concentration collector region is formed. The structure of the semiconductor device according to this exemplary embodiment is explained with reference to FIG. 5. FIG. 5 is a cross-sectional diagram illustrating the structure of the semiconductor device. The explanation common to the first exemplary embodiment is omitted or simplified as appropriate.

As shown in FIG. 5, a buried high concentration collector region 32b is formed in the transistor 30. That is, in this exemplary embodiment, the high concentration collector region 32 is composed of a high concentration contact collector region 32a and a buried high concentration collector regions 32b. The high concentration contact collector region 32a has substantially the same shape and size or the like with the high concentration collector regions of the first exemplary embodiment. In the transistor 40, the high concentration collector region 42 is composed of a high concentration contact collector region 42a and a buried high concentration collector region 42b as with the transistor 30. It is noted that in the transistors 30 and 40, the size and the positional relationship or the like of the corresponding components except the buried high concentration collector regions 32b and 42b are substantially the same.

The buried high concentration collector regions 32b and 42b respectively contact the lower parts of the high concentration contact collector regions 32a and 42a. The sizes of the buried high concentration collector regions 32b and 42b are different in the transistors 30 and 40. The position of the buried high concentration collector regions 32b and 42b in the height direction is the same. More specifically, the widths of the buried high concentration collector regions 32b and 42b are different. That is, in the transistor 30 which emphasizes high withstand voltage, the buried high concentration collector region 32b has a narrow width, while in the transistor 40 which emphasizes operating speed with low withstand voltage, the buried high concentration collector region 42b has a wide width.

In the transistor 30, the buried high concentration collector region 32b is formed to only nearby the high concentration contact collector region 32a. Further, in the transistor 40, the buried high concentration collector region 42b is formed so as to extend from the high concentration contact collector region 42a to a position below the edge of the base region 43 farther from the high concentration contact collector region 42a. Accordingly, the buried high concentration collector region 42b is formed to overlap with the base region 43 when viewed from above. In each of the transistors 30 and 40, the base regions 33 and 43 and the buried high concentration collector regions 32b and 42b are spaced apart.

As with the third exemplary embodiment, in the transistors 30 and 40, only the sizes of the buried high concentration collector regions 32b and 42b are different and the size and the positional relationship or the like of the other corresponding components are substantially the same. This facilitates the transistor design having different withstand voltages. To change the withstand voltage design of the product which has already been designed, it only requires to modify the mask to determine the high concentration collector regions 32 and 42. This simplifies the design change.

As described so far, the distances between the high concentration collector regions 32 and 42 and the base regions 33 and 43 change by changing the sizes, specifically the width, of the buried high concentration collector regions 32b and 42b. In this exemplary embodiment, the buried high concentration collector region 42b and the base region 43 are formed to overlap when viewed from above. Therefore, in the transistor 40, the distance of the horizontal direction between the high concentration collector region 42 and the base region 43 is 0. Further, the distance d1 between the high concentration collector region 32 and the base region 33 is longer than 0. Therefore, the distance of the horizontal direction between the high concentration collector region 32 and the base region 33 is longer than the distance between the high concentration collector region 42 and the base region 43. As with the third exemplary embodiment, this enables to control the withstand voltage only by the sizes of the high concentration collector regions 32 and 42, and the transistors 30 and 40 with different withstand voltages can be easily formed.

The SIC structure as disclosed in Japanese Unexamined Patent Application Publication No. 7-231043 may be combined. If the SIC structure is used especially to the transistor 40 which has low withstand voltage and operates at high speed, higher operating speed can be expected and there can be more choices of transistors to be mounted.

### Fifth Exemplary Embodiment

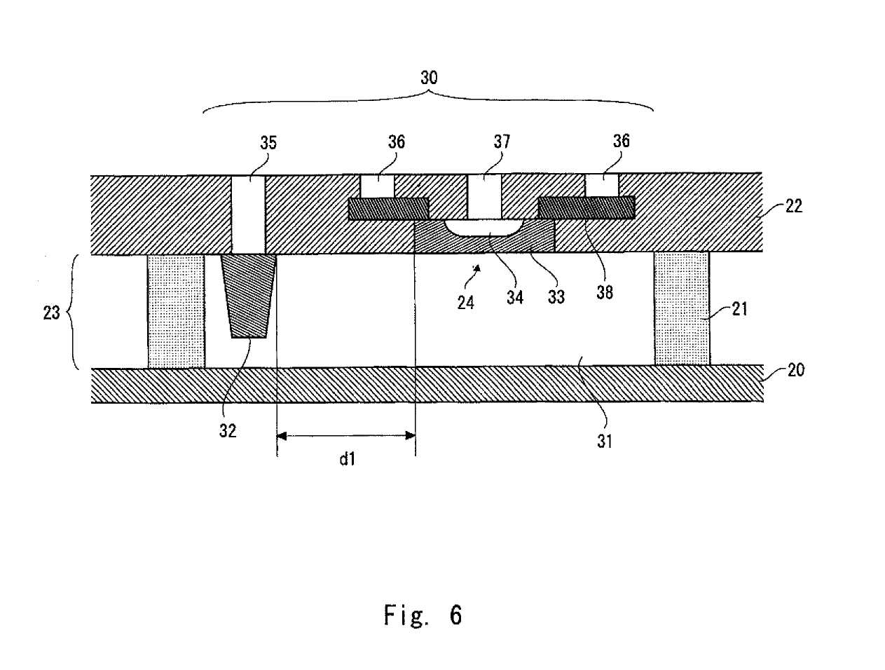

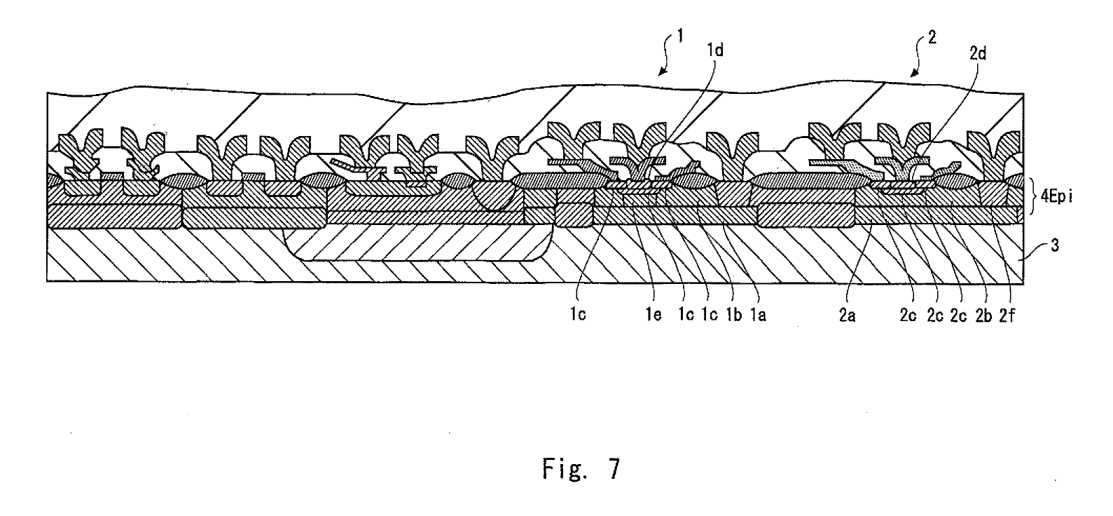

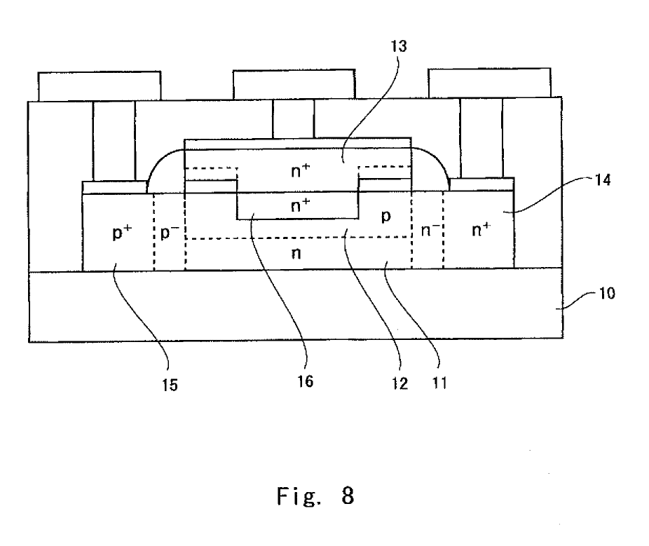

In this exemplary embodiment, a base region and an emitter region are formed over a body silicon layer. The structure of the semiconductor device according to this exemplary embodiment is explained with reference to FIG. 6. FIG. 6 is a cross-sectional diagram illustrating the structure of a semiconductor device. It is noted that only one transistor is illustrated in FIG. 6, however multiple transistors with different withstand voltages are formed as with the first exemplary embodiment. Further, the transistor 30 is explained as an example, however it is applicable also to the transistor 40. The explanation common to the first exemplary embodiment is omitted or simplified as appropriate.

As illustrated in FIG. 6, the low concentration collector region 31, the high concentration collector region 32, and the insulating layer 21 for separating elements are formed in the body silicon layer 23 over the insulating layer 20 of the SOI substrate in a similar way as the first exemplary embodiment. Over the body silicon layer 23, the base region 33, the emitter region 34, the base conductive layer 38, the insulating layer 22, the collector electrode 35, the base electrode 36, and the emitter electrode 37 are formed. For example, the base region 33 and the emitter region 34 are formed of an upper semiconductor layer 24. That is, the upper semiconductor layer 24 is formed over the body silicon layer 23. The upper semiconductor layer 24 is in contact with the main surface of the body silicon layer 23.

The base region 33 is formed in contact with the low concentration collector region 31 and the emitter region 34. The base region 33 is formed to surround the emitter region 34 except an upper edge. The base region 33 may be formed by an epitaxial layer including germanium, for example. Accordingly, the upper semiconductor layer 24 may be an epitaxial layer including germanium, for example. With this structure, it is possible to apply to transistors with higher performance, such as a transistor using an epitaxial layer including germanium.

A base conductive layer 38 is formed in contact with the upper edge of the base region 33. The base conductive layers 38 are formed to the both opposite ends of the base region 33 respectively, and are extended to the opposite side to the emitter region 34. Then, the collector electrode 35 is formed in contact with the high concentration collector region 32. Two base electrodes 36 are formed in contact with the two base conductive layers 38. The emitter electrode 37 is formed in contact with the emitter region 34. Then, the insulating layer 22 is formed in the other part. Thus, it is possible to form transistors with different withstand voltages over one substrate easily by adjusting the distance between the high collector regions and the base regions for each transistor.

The first to fifth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a semiconductor layer;
a low withstand voltage transistor in which a first high concentration collector region and a first base region contact with a first low concentration collector region provided in the semiconductor layer; and
a high withstand voltage transistor in which a second high concentration collector region and a second base region contact with a second low concentration collector region provided in the semiconductor layer, the second high concentration collector region and the second base region being configured such that the distance between the second high concentration collector region and the second base region in a parallel direction to a main surface of the semiconductor layer is longer than the distance between the first high concentration collector region and the first base region.

2. The semiconductor device according to claim 1, wherein the first high concentration collector region is provided to both sides of the first base region.

3. The semiconductor device according to claim 1, wherein a width of the second high concentration collector region is narrower than a width of the first high concentration collector region.

4. The semiconductor device according to claim 2, wherein a width of the second high concentration collector region is narrower than a width of the first high concentration collector region.

5. The semiconductor device according to claim 1, wherein
the first high concentration collector region comprises a first high concentration contact collector region and a first buried high concentration collector region, and
the second high concentration collector region comprises a second high concentration contact collector region and a second buried high concentration collector region that has a narrower width than the first buried high concentration collector region.

6. The semiconductor device according to claim 2, wherein
the first high concentration collector region comprises a first high concentration contact collector region and a first buried high concentration collector region, and
the second high concentration collector region comprises a second high concentration contact collector region and a second buried high concentration collector region that has a narrower width than the first buried high concentration collector region.

7. The semiconductor device according to claim 3, wherein
the first high concentration collector region comprises a first high concentration contact collector region and a first buried high concentration collector region, and
the second high concentration collector region comprises a second high concentration contact collector region and a second buried high concentration collector region that has a narrower width than the first buried high concentration collector region.

8. The semiconductor device according to claim 4, wherein
the first high concentration collector region comprises a first high concentration contact collector region and a first buried high concentration collector region, and
the second high concentration collector region comprises a second high concentration contact collector region and a second buried high concentration collector region that has a narrower width than the first buried high concentration collector region.

9. The semiconductor device according to claim 1, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

10. The semiconductor device according to claim 2, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

11. The semiconductor device according to claim 3, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

12. The semiconductor device according to claim 4, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

13. The semiconductor device according to claim 5, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

14. The semiconductor device according to claim 6, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

15. The semiconductor device according to claim 7, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.

16. The semiconductor device according to claim 8, further comprising an upper semiconductor layer that is provided in contact with the semiconductor layer over the semiconductor layer, wherein
the first high concentration collector region, the second high concentration collector region, the first low concentration collector region, and the second low concentration collector region are formed in the semiconductor layer, and
the first base region and the second base region are formed in the upper semiconductor layer.
